(19) United States
(12) Patent Application Publication
(10) Pub. No.: US 2012/0249151 A1
(43) Pub. Date: Oct. 4, 2012

(54) RESIDUAL-CURRENT CIRCUIT BREAKER

(75) Inventors: Gerhard Dobusch, Wien (AT); Roman Kolm, Schweiggers (AT)

(73) Assignee: Eaton GmbH, Schrems (AT)

(21) Appl. No.: 13/246,401

(22) Filed: Sep. 27, 2011

Related U.S. Application Data
(60) Provisional application No. 61/387,231, filed on Sep. 28, 2010.

(30) Foreign Application Priority Data
Sep. 28, 2010 (AT) A 1620/2010

(51) Int. Cl. G01R 31/327

(52) U.S. Cl. 324/424

(57) ABSTRACT

A compact residual-current circuit breaker constructed for functional testing without any interruption of the downstream electric network includes two separate tripping circuits, wherein a first tripping circuit is independent of the mains voltage and a second tripping circuit is dependent on the mains voltage. During functional testing one of the tripping circuits the respective other tripping circuit monitors the electric network to be protected for fault currents.

### CROSS-REFERENCES TO RELATED APPLICATIONS

This application claims the benefit of prior filed U.S. provisional Application No. 61/387,231, filed Sep. 28, 2010, pursuant to 35 U.S.C. 119(e), the content of which is incorporated herein by reference in its entirety as if fully set forth herein.

This application also claims the priority of Austrian Patent Application, Serial No. A 1620/2010, filed Sep. 28, 2010, pursuant to 35 U.S.C. 119(a)-(d), the content of which is incorporated herein by reference in its entirety as if fully set forth herein.

### BACKGROUND OF THE INVENTION

The present invention relates to a residual-current circuit breaker.

The following discussion of related art is provided to assist the reader in understanding the advantages of the invention, and is not to be construed as an admission that this related art is prior art to this invention.

Residual-current circuit breakers usually have a testing device in order to check the effectiveness of tripping of the respective residual-current circuit breaker during the occurrence of a fault current. An electric circuit is closed by means of a key button for example, in which a current is guided past a residual-current detector such as a summation current transformer. Such a current will be detected by a functional residual-current circuit breaker as a fault current, whereupon the break contacts are disconnected in a functional residual-current circuit breaker and the subsequent electric network to be protected by the residual-current circuit breaker is switched off or is disconnected from another upstream electric network.

The disadvantageous aspect is that all electrical components connected to the respective network to be protected will be currentless for a certain period of time in the case of smooth functioning of the respective residual-current circuit breaker until the renewed activation of the respective residual-current circuit breaker and will therefore be deactivated. Modern households have a large number of electrical appliances which require a continuous supply with electric power and which need to be put back into operation again individually by hand after a power failure, which requires more or less work. In addition to the clocks which are provided in numerous appliances and which require a renewed setting of the time, programmable devices such as audio, video and/or TV devices will lose the settings made by the user. Although the loss of the time and the personal settings in electronic appliances is unpleasant for the individual user and represents one of the main reasons for the low acceptance of functional tests in residual-current circuit breakers, the interruption of the power supply in the course of the functional test of the residual-current circuit breaker can further lead to safety risks if machines are switched off during operation for reasons of lack of knowledge of the actual electric circuits concerned by the functional test.

It is therefore the object of the invention to provide a residual-current circuit breaker of the kind mentioned above with which the mention disadvantages can be avoided, in which

It would therefore be desirable and advantageous to address this problem and to obviate other prior art shortcomings by providing a compact residual-current circuit breaker wherein a functional test can be performed without interrupting the downstream electric network.

### SUMMARY OF THE INVENTION

According to one aspect of the present invention, a residual-current circuit breaker includes first break contacts which can be predeterminably disconnected, second break contacts which can be predeterminably actuated and which, when closed, bridge the first break contacts, a first tripping circuit comprising at least one first residual-current sensor and being operatively connected with the first break contacts for opening the first break contacts in a manner independent of the mains voltage during occurrence of a fault current of predeterminable magnitude, a control unit operatively connected with the second break contacts and including a first test switch which is part of a first test current path for generating a first simulated fault current operating on the first tripping circuit, a second tripping circuit having at least one second residual-current sensor which is at least indirectly connected with the control unit by means of circuitry, wherein the control unit is operatively connected with a second test switch which is part of a second test current path for generating a second simulated fault current acting on the second tripping circuit, and a testing arrangement for functional testing of the first and the second tripping circuit, wherein the testing arrangement includes a test button which operates on the control unit.

A residual-current circuit breaker can be formed thereby in which a functional test can be performed without such a test inevitably leading to an interruption of the current flow in the downstream electric network. Since the renewed programming of electronic appliances as a consequence of a power failure can be avoided, the functional test of such residual-current circuit breakers will have a higher acceptance than the functional test of conventional residual-current circuit breakers. As a result, effective residual-current circuit breakers will be detected at an earlier time than before and can be exchanged. In this way, the security of electric installations will increase. As a result, the functional test can be performed in an automated way at specific points in time by the respective residual-current circuit breaker.

By arranging the first tripping circuit as a tripping circuit independent of mains voltage which monitors the electric circuit to be protected in the normal operation of the residual-current circuit breaker concerning occurring fault currents, such a residual-current circuit breaker can also be used in countries which have respective national or regional regulations concerning the required use of residual-current circuit breakers which are independent of mains voltages. As a result of the dependency of the second tripping circuit on mains voltage, the second residual-current sensor can be provided with a smaller configuration than the first residual-current sensor since the second residual-current signal determined by the second residual-current sensor can be less powerful as a result of the subsequent active signal amplification than the first residual-current signal which is determined by the first residual-current sensor. The second residual-current sensor can be provided with a much smaller and more compact configuration especially in the case of a preferred configuration of the first and the second residual-current sensor as a summation current transformer. Furthermore, lower requirements are placed on the employed core material, so that the costs for a second residual-current sensor arranged in this manner will be low. Consequently, the overall size of the residual-current circuit breaker can be kept at a low level. The pertinent residual-current circuit breaker is a so-called residual-current circuit breaker which is independent of mains voltage despite the dependence of the second tripping circuit on mains voltage since mains voltage is only required during the process of the functional test and only for this process, as is the case in all residual-current circuit breakers with a respective functional test.

According to another aspect of the invention, a method for functional testing of a residual-current circuit breaker with a first tripping circuit and a second tripping circuit and with first and second break contacts includes the steps of, while the first break contacts are closed, monitoring with the first tripping circuit an electric network to be protected independent of a mains voltage for occurrence of fault currents, actuating a test button test button operating on a control unit to close second break contacts which bridge the first break contacts, generating a second simulated fault current for testing the second tripping circuit, electrically amplifying a second residual-current signal determined by the second tripping circuit and checking if the amplified second residual-current signal exceeds or falls below a predetermined tripping threshold, opening the second break contacts if the amplified second residual-current signal exceeds or falls below the predetermined tripping threshold, closing the second break contacts if the amplified second residual-current signal exceeds or falls below the predetermined tripping threshold, generating a first simulated fault current for testing the first tripping circuit, checking a first residual-current signal determined by the first tripping circuit to determine if the first residual-current signal exceeds a predeterminable tripping threshold independent of the mains voltage, and opening the first break contacts if the first residual-current signal exceeds the tripping threshold.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 shows a schematic diagram of an exemplary embodiment of a residual-current circuit breaker in accordance with the present invention in the voltage-free state; p FIG. 2 shows a schematic diagram of the residual-current circuit breaker of FIG. 1 in normal operation; and

FIG. 3 shows a schematic diagram of the residual-current circuit breaker of FIG. 1 during a testing process.

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. It should also be understood that the figures are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted.

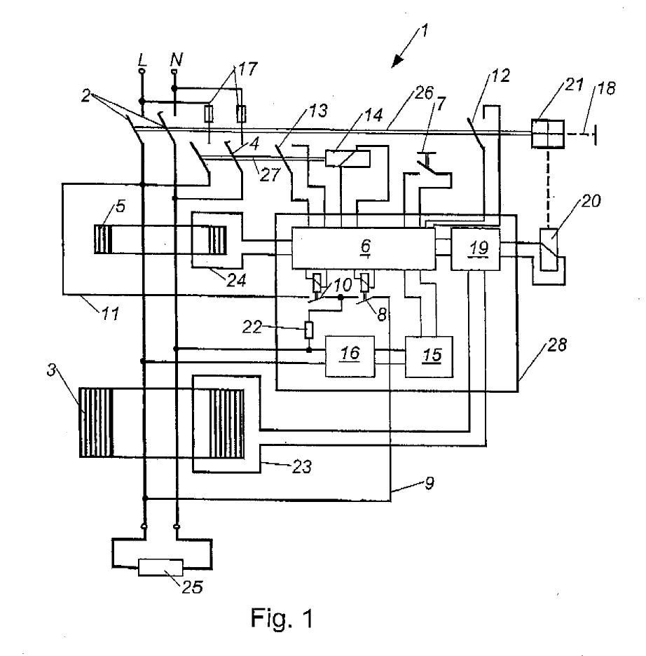

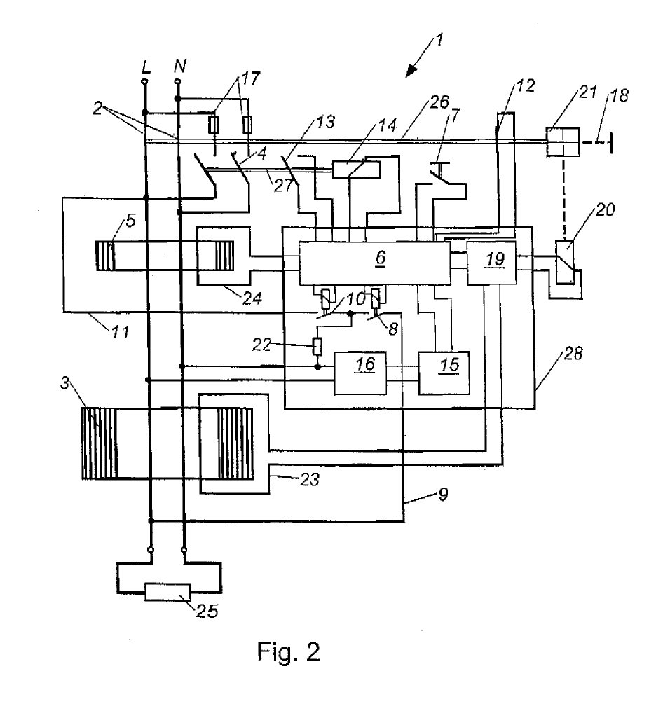

Turning now to the drawing, there is shown in FIGS. 1 to 3 a residual-current circuit breaker 1 with a first tripping circuit and a second tripping circuit, with the residual-current circuit breaker 1 having first break contacts 2 which can be disconnected in a predetermined manner, with the first tripping circuit comprising at least one first residual-current sensor 3 and being operatively connected with the first break contacts 2 for opening in a manner independent of the mains voltage the first break contacts 2 during the occurrence of a fault current of predeterminable magnitude, with the residual-current circuit breaker 1 having second break contacts 4 which can be actuated in a predeterminable manner and which bridge the first break contacts 2 in the closed state, with the second tripping circuit having at least one second residual-current sensor 5, with the second residual-current sensor 5 being connected at least indirectly by means of circuitry with a control unit 6, with the control unit 6 being operatively connected with the second break contacts 2, with the residual-current circuit breaker 1 having a testing arrangement for functional testing of the first and the second tripping circuit, with the testing arrangement having a test button 7 which acts upon the control unit 6, with the control unit 6 being operatively connected with a first test switch 8, which first test switch 8 is part of a first test current path 9 for generating a first simulated fault current acting upon the first tripping circuit, and with the control unit 6 being operatively connected with a second test switch 10, which second test switch 10 is part of a second test current path 11 for generating a second simulated fault current acting on the second tripping circuit.

A residual-current circuit breaker 1 can thereby be formed in which a functional test can be performed without this inevitably leading to an interruption of the current flow in the downstream electric network. Since the renewed programming of electronic devices as a consequence of a power failure can be avoided, the functional test of such residual-current circuit breakers 1 has a higher acceptance than the functional test of conventional residual-current circuit breakers. Defective residual-current circuit breakers 1 will thereby be detected at an earlier time than is currently the case and can be exchanged. This increases the safety of electrical installations. As a result, the functional test can be performed in an automated manner at a certain point in time by the respective residual-current circuit breaker 1.

By arranging the first tripping circuit as a tripping circuit independent of mains voltage which monitors the electric circuit to be protected in the normal operation of the residual-current circuit breaker 1 concerning occurring fault currents, such a residual-current circuit breaker 1 can also be used in countries which have respective national or regional regulations concerning the required use of residual-current circuit breakers 1 which are independent of mains voltages. As a result of the dependency of the second tripping circuit on mains voltage, the second residual-current sensor 5 can be provided with a smaller configuration than the first residual-current sensor 3 since the second residual-current signal determined by the second residual-current sensor 5 can be less powerful as a result of the subsequent active signal amplification than the first residual-current signal which is determined by the first residual-current sensor 3. The second residual-current 5 sensor can be provided with a much smaller and more compact configuration especially in the case of a preferred configuration of the first and the second residual-current sensors 3, 5 as a summation current transformer. Furthermore, lower requirements are placed on the employed core material, so that the costs for a second residual-current sensor 5 arranged in this manner will be low. Consequently, the overall size of the residual-current circuit breaker 1 can be kept at a low level. The pertinent residual-current circuit breaker 1 is a so-called residual-current circuit breaker 1 which is independent of mains voltage despite the dependence of the second tripping circuit on mains voltage since mains voltage is only required during the process of the functional test and only for this process, as is the case in all residual-current circuit breakers 1 with a respective functional test.

It is proposed in such a residual-current circuit breaker 1 for functional testing without interruption of the downstream electric network and for achieving a compact configuration that the residual-current circuit breaker 1 includes two separate tripping circuits, with a first tripping circuit being arranged to be independent of mains voltage and with a second tripping circuit being arranged to be dependent on mains voltage. During the functional test of the one tripping circuit the respectively other tripping circuit monitors the electric network to be protected for fault currents.

FIGS. 1 to 3 show an especially preferred embodiment of a residual-current circuit breaker 1 in accordance with the invention in different operating states. The preferred configuration of a residual-current circuit breaker 1 in accordance with the invention will be explained below by reference to FIGS. 1 to 3.

Residual-current circuit breakers 1 are provided for the protection of an electric network or a partial network from fault currents or earth fault currents. An electric network preferably includes at least two conductors L, N, wherein embodiments with more conductors such as three or four can be provided. The residual-current circuit breaker 1 includes input and output terminals (not shown) for the connection of the conductors L, N. The residual-current circuit breaker 1 further includes first break contacts 2 which are arranged to be disconnected in the case of a fault and to deactivate or disconnect the network to be protected.

The residual-current circuit breaker 1 further includes a first and second residual-current sensor 3, 5 which are preferably arranged as summation current transformers. It is also possible to provide other embodiments of the residual-current sensors 3, 5. It can also be provided that the 2 residual-current sensors 3, 5 are each arranged in different ways, e.g. it can be provided to arrange the first residual-current sensor 3 as a summation current transformer and the second residual-current sensor 5 as a Förster probe or as an arrangement of shunt resistors. The summation current transformers each include a preferably annular core with a lead-through opening, through which the conductors L, N of the network to be monitored and protected are guided. The first and second residual-current detectors 3, 5 which are arranged as summation current transformers are shown in FIGS. 1 to 3 as schematic sectional views of the core.

Residual-current circuit breakers 1 in accordance with the invention include a first and second tripping circuit.

The first tripping circuit is provided for monitoring the electric network to be protected for the occurrence of fault currents in regular operation of the residual-current circuit breaker 1 in accordance with the invention, therefore in operation outside of the testing process, and includes the first residual-current sensor 3 which is arranged as a summation current transformer. A so-called first secondary winding 23 is arranged around the core of the summation current transformer, in which a first residual-current signal is generated during the occurrence of a fault current. The first tripping circuit is arranged as a so-called tripping circuit which is independent of mains voltage and therefore for opening the first break contacts 2 independent of mains voltage during the occurrence of a fault current of predeterminable magnitude since the entire energy required for tripping the residual-current circuit breaker 1 is taken from the first residual-current signal, the core of the first summation current transformer preferably includes a high-quality magnetic material. The core must also have a certain size in order to generate a first residual-current signal in the case of a fault which has the required power in order to subsequently cause an opening of the first break contacts 2.

The first secondary winding 23 is preferably connected to a tripping unit 19 in which preferably an energy storage element such as the capacitor and a comparator circuit are arranged in order to compare the first residual-current signal with a reference signal. The tripping unit 19 is connected according to FIGS. 1 to 3 to a tripping relay 20 which can also be arranged as a permanent magnet trip for example and which mechanically acts on a breaker mechanism 21. During the occurrence of a fault current, a first residual-current signal is generated in the first secondary winding 23 which is compared with a reference signal in the tripping unit 19. If the first residual-current signal exceeds the reference signal, the tripping relay 20 is actuated which acts upon the breaker mechanism 21 and unlatches the same, thus causing an opening of the first break contacts 2. The manual operation lever 18 is connected with the breaker mechanism. The first break contacts can be closed with them again and the breaker mechanism 21 can be latched.

The second tripping circuit includes a second residual-current sensor 5 which is also preferably arranged as a summation current transformer, with a second secondary winding 24 being arranged around its core cross-section which is connected to a control unit 6 which is preferably arranged as a programmable logic circuit and/or microcontroller or includes such a one. The control unit 6 further preferably includes an amplifier circuit in order to actively amplify the incoming second residual-current signal. As a result, the core of the second residual-current sensor 5 which is arranged as a summation current transformer can be arranged in a substantially smaller way and with a magnetic material of lower quality than the core of the first residual-current sensor 3 which is arranged as a summation current transformer.

A power unit 16 is provided for the power supply of the control unit 6, which power unit is connected with at least two conductors L, N of the network to be protected. The power unit 16 is preferably arranged for the purpose of conditioning the voltage on the mains side for the supply of the control unit 6. The power unit 16 includes a rectifier in an especially preferable way. It is preferably provided that the control unit 6 is connected by way of circuitry with an energy storage element 15, especially a storage battery or a capacitor, which energy storage element 15 is connected with the power unit 16. As a result, further operation of the control unit 6 can be ensured even in the case of loss of the mains voltage during operation of the second tripping circuit. In this way, the second tripping circuit is also independent of mains voltage since the power required for the time-limited operation of the second tripping circuit or the control unit 6 is taken from the energy storage element 15 and is therefore provided independent of mains voltage.

A residual-current circuit breaker 1 in accordance with the invention further includes second break contacts 4 in addition to the already explained first break contacts 2, which second break contacts bridge the first break contacts 2 in the closed state. The second break contacts 4 are operatively connected with the control unit 6 and can be actuated by the same in a predeterminable manner. A second actuator 14 is provided according to the illustrated preferred embodiment, which second actuator is triggered by the control unit 6 and with which the second break contacts 4 can be opened or closed. As is illustrated in FIGS. 1 to 3 by a double line, the second actuator 14 is mechanically coupled with the second break contacts 4.

The second break contacts 4 are provided for bridging the first break contacts 2 for the duration of the testing of the first tripping circuit and ensuring the current flow through the residual-current circuit breaker 1 for this limited period of time which is preferably under one second and disconnecting the same in the event of a fault. FIGS. 1 to 3 show the bridging of the first break contacts 2 by the second break contacts. Due to the lower duration of a potential current flow via the second break contacts 4, they can be provided with a smaller configuration and with materials of lower quality than the first break contacts 2. This contributes to the small overall size of a residual-current circuit breaker 1 in accordance with the invention.

In order to increase the safety during operation of the second break contacts 4, it is provided according to a preferred further development of the present invention that at least one fuse 17 is arranged serially in relation to the second break contacts 4, which fuse also bridges the first break contacts 2. It is especially provided that at least one fuse 17 is arranged serially in relation to each of the second break contacts. The fuses 17 protect the second break contacts 4 from fusing in the event of a short-circuit occurring in the network during the testing process.

It is provided according to a preferred embodiment of the present invention that a second auxiliary contact 13 is mechanically coupled with the second break contacts 4. Said second auxiliary contact 13, which has the same switching position as the second break contacts 4 as a result of mechanical coupling, is connected by way of circuitry with the control unit 6, thereby enabling the control unit to query the switching position of the second break contacts 4.

It is preferably also provided that a first auxiliary contact 12 is mechanically coupled with the first break contacts 2, with said first auxiliary contact 12 also being preferably connected to the control unit 6, thus enabling the control unit to query the switching position of the first break contacts 2.

FIGS. 1 to 3 further show a load 25 in the form of an ohmic resistor not designated in closer detail. Furthermore, certain functional modules which are required for tripping the residual-current circuit breaker 1 are arranged in FIGS. 1 to 3 in a block 28, which preferably cannot have any function itself.

Residual-current circuit breakers 1 in accordance with the invention further include a testing arrangement for functional testing of the first and second tripping circuit. The testing arrangement includes a test button 7 which is operatively connected by means of circuitry with the control unit 6 and with which the control unit 6 is provided with the task of performing the test. The further functional testing occurs in a manner controlled by the control unit 6 and will be explained below following the description of the constructional configuration of a residual-current circuit breaker 1 in accordance with the invention.

The testing arrangement includes a first test current path 9 which is provided and arranged for generating a first simulated fault current acting on the first tripping circuit. The first test current path 9 includes a test resistor 22 and a first test switch 8 for this purpose according to the illustrated preferred embodiment, which first test switch 8 is operatively connected with the control unit 6 and is triggered by the same. The first test current path 9 further includes an electric line which leads from the conductor L of the network to be protected past the summation current transformer of the first residual-current sensor 3 on the outside to the first test switch 8, and from there further to the test resistor 22 and by means of a further line to the conductor N of the network. The first test current path 9 thus connects two conductors N, L of an electric network to be protected and bridges the first fault current sensor 3.

The testing arrangement further includes a second test current path 11 which is provided and arranged for generating a second simulated fault current acting on the second tripping circuit. In accordance with the illustrated preferred embodiment, the second test current path 11 includes a test resistor 22 and a second test switch 10, which second test switch 10 is operatively connected with the control unit 6 and is triggered by the same. The second test current path 11 further includes an electric line which leads from the conductor L of the network to be protected past the summation current transformer of the second residual-current sensor 5 on the outside to the second test switch 10, and from there further to the test resistor 22 and by means of a further line to the conductor N of the network. The second test current path 11 thus connects two conductors N, L of an electric network to be protected and bridges the second fault current sensor 5. As already explained above, it is especially preferable that the first and the second test current path 9, 11 each use the same test resistor 22, so that the test resistor 22 is part of the first and also the second test current path 9, 11.

Preferably, the first test current path 9 and the second test current path 11 are each arranged in such a way that a potentially occurring leakage current caused by the installation is added up once and subtracted once. In the case of an addition of a leakage current into a test current, a higher fault current than intended would be generated. If the residual-current circuit breaker should trip under these conditions, it is therefore not possible to conclude that the respective residual-current circuit breaker would also trip under a rated fault current. It can further be expected that in the case of a subtraction of the leakage current from the test current the residual-current circuit breaker would not trip because the rated fault current would not be reached. Such a residual-current circuit breaker would therefore erroneously be regarded as non-functional. As a result of the preferred evaluation of the first and second residual-current signals by the control unit 6, it is possible to draw conclusions on the occurrence of such leakage currents which will also superimpose the tripping behavior in the test case. In this way the functioning of the residual-current circuit breaker under rated current can actually be tested and optionally a warning can be generated for the user.

The arrangement of the first and/or second test current path 9, 11 can also be arranged in respect of circuitry or construction alternatively to the preferred embodiment as described above.

The first and/or the second test switch 8, 10 are preferably arranged as electromechanical relays. It is also possible to provide other switches such as semiconductor switches, especially thyristors or transistors.

It is provided according to an especially preferred further development of the present invention in addition to the already described modules of a preferred embodiment of a residual-current circuit breaker 1 in accordance with the invention that the residual-current circuit breaker 1 includes at least one first actuator which is triggered by the control unit 6 and which is mechanically coupled with the first break contacts 2. The control unit can thus produce the closing and special opening of the first break contacts.

In addition to the constructional configuration of a residual-current circuit breaker 1, the present invention further relates to a method for functional testing of a residual-current circuit breaker 1, especially one in accordance with the invention, comprising a first tripping circuit and a second tripping circuit, and closed first break contacts 2, with an electric network to be protected being monitored by the first tripping circuit independent of mains voltage for the occurrence of fault currents, with second break contacts 4 which bridge the first break contacts 2 being closed upon actuation of a test button 7, with subsequently a second simulated fault current being generated for testing the second tripping circuit, with a second residual-current signal determined by the second tripping circuit being electrically amplified and being checked for exceeding or falling below a predeterminable tripping threshold, and with the second break contacts 4 being opened upon exceeding or falling below the tripping threshold by the second fault-current signal, with subsequently the second break contacts 4 being closed (preferably only) upon exceeding the tripping threshold by the second fault-current signal, with subsequently a first simulated fault current being generated for testing the first tripping circuit, with a first residual-current signal determined by the first tripping circuit being checked independent of mains voltage for exceeding a predeterminable tripping threshold, with the first break contacts 2 being opened upon exceeding the tripping threshold by the first residual-current signal.

Notice must be taken that the information concerning a first and a second simulated fault current or a first and second residual-current signal need not relate to the time sequence of their generation, but were chosen preferably with respect to the designation of the involved apparatuses. That is why the designation of first simulated fault current does not mean that it is inevitably generated as the first one, but that it is generated by the first test current path and is provided for testing the first tripping circuit.

The electric network protected is monitored by the first tripping circuit independent of mains voltage for the occurrence of fault currents during the error-free and test-free operation of the residual-current circuit breaker 1. The respective state is shown in FIG. 2.

When the test button 7 is actuated, the second break contacts 4 are closed especially by the control unit 6 and the first break contacts 2 are bridged thereby. The switching position of the second break contacts 4 is monitored by the control unit 6 preferably with the help of the optional second auxiliary contact 13, so that a potential error source of the method is securely monitored. As a result, fused contacts of the second break contacts 4 can thereby be recognized.

Subsequently, a second simulated fault current is generated for testing the second tripping circuit. It is preferably provided that a second test current path 11 is closed for a predeterminable second time interval for generating the second simulated fault current by the control unit 6. The second time interval is preferably shorter than one second, especially approximately 300 ms to 500 ms. As a result of the short duration of the entire testing process, the components required for this purpose can be provided with a small configuration concerning the power loss to be discharged and the power supply.

A second fault currents signal which is determined as a consequence of the second fault current by the second tripping circuit is electrically amplified in the control unit 6 for example or in a separate amplifier and is checked for exceeding or falling below a predeterminable and stored tripping threshold. The second break contacts 4 are opened both during the exceeding and falling below the tripping threshold by the second fault-current signal. If the second fault current signal exceeds the tripping threshold or if both values correspond precisely, it is subsequently provided that the second break contacts 4 are closed. If the tripping threshold is not reached by the second residual-current signal, it is provided that the second break contacts 4 are not closed again. Instead, the test will be terminated and an error will be indicated by means of a control lamp for example.

In the event that the second fault current signal has exceeded the tripping threshold and subsequently the second break contacts 4 are closed again, which is optionally checked by way of the second auxiliary contact 13 by the control unit 6, a first simulated fault current is subsequently generated for testing the first tripping circuit. It is preferably provided in this case that for generating the first simulated fault current by the control unit 6 a first test current path 9 will be closed for a predeterminable first duration. The first duration is preferably shorter than one second, especially approximately 300 ms to 500 ms.

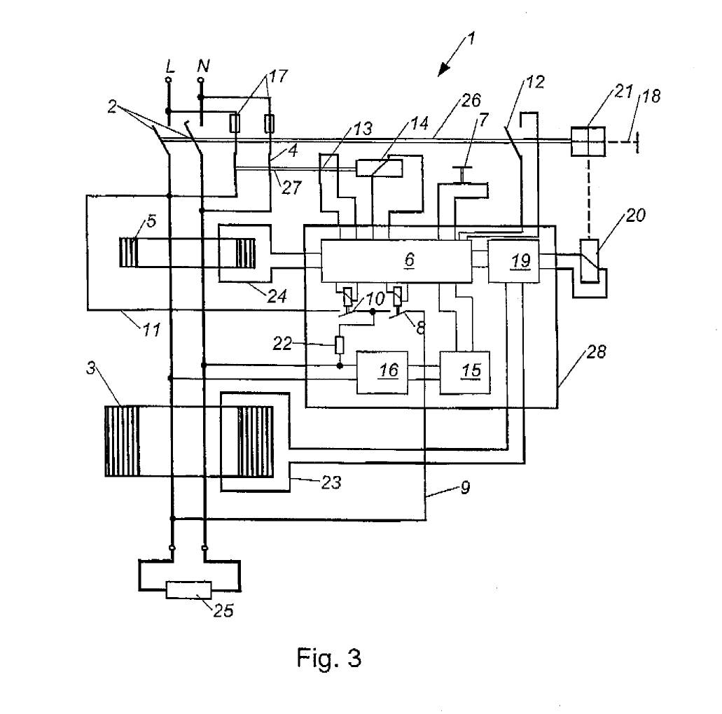

The first residual-current signal which is determined as a consequence of the simulated first fault current by the first tripping circuit is checked independent of mains voltage for exceeding a predeterminable tripping threshold, with the first break contacts 2 being opened upon exceeding the tripping threshold by the first residual-current signal. The respective state is shown in FIG. 3. It can preferably be provided that the first residual-current signal is additionally read and monitored by the control unit 6, and/or that further electrical states such as the charging curve of an energy storage element which is preferably arranged in the tripping unit 19 are monitored by the control unit 6. It is subsequently preferably provided that the first break contacts 2 are closed, especially by the control unit 6. While the first break contacts 2 are opened, the load current flows via the second break contacts 4, whereas the second tripping circuit ensures the protection from fault current. It is preferably provided in a further development to store the energy for the automatic closing of the first break contacts 2 already during actuation of the test button 7 in an energy storage element (not shown), as a result of which this process is not dependent on mains voltage and the residual-current circuit breaker 1 can also be switched on again even in the case of a loss of the mains voltage in the meantime.

The advantages as asserted initially can be achieved by the method steps as explained above.

During functional testing of the first tripping circuit, especially exclusively during this functional testing, the electric network to be protected is monitored by the second tripping circuit for the occurrence of fault currents. It is preferably provided that the control unit 6 is supplied with electric power during the functional testing of the second tripping circuit by an energy storage element 15. A virtual independence from the mains voltage is thereby achieved because the electric power which is required for the time-limited operation of the control unit is taken from the energy storage element 15. Such a large amount of energy is preferably stored in the energy storage element 15 in order to reliably supply the second tripping circuit during interruption of a conductor L, N of the network to be protected during its operation until the renewed activation of the first tripping circuit on the one hand or in order to switch off the second break contacts 4 during line interruptions and simultaneous fault current on the other hand.

In accordance with an especially preferred further development of the method in accordance with the invention it is provided that if the first break contacts are not closed again within a predeterminable period of time, preferably shorter than 5 seconds, especially approximately 3 seconds, after a performed test of the first tripping circuit, the second break contacts 4 are opened by the control unit. Miniaturization of the second break contacts can thereby be further supported because they merely need to be configured for current flow over a short period of time.

It is preferably further provided that the control unit 6 is arranged in such a way that during the occurrence of states or procedures which deviate from the information provided above a fault signal is output, branched off or forwarded.

If a drop in the voltage occurs in the network to be protected during the testing process, the second break contacts 4 are preferably opened by the control unit 6 and the test process is terminated.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

What is claimed is:

1. A residual-current circuit breaker, comprising:
first break contacts which can be predeterminably disconnected, second break contacts which can be predeterminably actuated and which, when closed, bridge the first break contacts,
a first tripping circuit comprising at least one first residual-current sensor and being operatively connected with the first break contacts for opening the first break contacts in a manner independent of the mains voltage during occurrence of a fault current of predeterminable magnitude,
a control unit operatively connected with the second break contacts and comprising a first test switch which is part of a first test current path for generating a first simulated fault current operating on the first tripping circuit,
a second tripping circuit having at least one second residual-current sensor which is at least indirectly connected with the control unit by means of circuitry, wherein the control unit is operatively connected with a second test switch which is part of a second test current path for generating a second simulated fault current acting on the second tripping circuit, and
a testing arrangement for functional testing of the first and the second tripping circuit, wherein the testing arrangement comprises a test button which operates on the control unit.

2. The residual-current circuit breaker of claim 1, further comprising a first auxiliary contact which is mechanically coupled with the first break contacts.

3. The residual-current circuit breaker of claim 1, further comprising a second auxiliary contact which is mechanically coupled with the second break contacts.

4. The residual-current circuit breaker of claim 1, further comprising at least one first actuator which is triggered by the control unit and which is mechanically coupled with the first break contacts.

5. The residual-current circuit breaker of claim 1, further comprising at least one second actuator which is triggered by the control unit and which is mechanically coupled with the second break contacts.

6. The residual-current circuit breaker of claim 1, wherein the control unit is connected by way of circuitry with an energy storage element which is connected to a power supply.

7. The residual-current circuit breaker of claim 6, wherein the energy storage element comprises a storage battery or a capacitor.

8. The residual-current circuit breaker of claim 1, wherein the first test current path connects a neutral conductor and a phase conductor of an electric network to be protected and bridges the first residual-current sensor.

9. The residual-current circuit breaker of claim 1, wherein the second test current path connects a neutral conductor and a phase conductor of an electric network to be protected and bridges the second residual-current sensor.

10. The residual-current circuit breaker of claim 1, further comprising at least one fuse bridging the first break contacts, wherein the at least one fuse is connected in series with the second break contacts.

11. A method for functional testing of a residual-current circuit breaker with a first tripping circuit and a second tripping circuit and with first and second break contacts, comprising the steps of:
while the first break contacts are closed, monitoring with the first tripping circuit an electric network to be protected independent of a mains voltage for occurrence of fault currents,
actuating a test button test button operating on a control unit to close second break contacts which bridge the first break contacts,
generating a second simulated fault current for testing the second tripping circuit,
electrically amplifying a second residual-current signal determined by the second tripping circuit and checking if the amplified second residual-current signal exceeds or falls below a predetermined tripping threshold,
opening the second break contacts if the amplified second residual-current signal exceeds or falls below the predetermined tripping threshold,
closing the second break contacts if the amplified second residual-current signal exceeds or falls below the predetermined tripping threshold,
generating a first simulated fault current for testing the first tripping circuit,
checking a first residual-current signal determined by the first tripping circuit to determine if the first residual-current signal exceeds a predeterminable tripping threshold independent of the mains voltage, and
opening the first break contacts if the first residual-current signal exceeds the tripping threshold.

12. The method of claim 11, further comprising the step of closing the first break contacts again, after the first break contacts have been opened.

13. The method of claim 12, wherein the first break contacts are closed again by the control unit.

14. The method of claim 11, further comprising the step of closing a second test current path for a predeterminable second duration for generating with the control unit the second simulated fault current.

15. The method of claim 11, further comprising the step of closing a first test current path for a predeterminable first duration for generating with the control unit the first simulated fault current.

16. The method of claim 11, wherein the electric network to be protected is monitored by the second tripping circuit for occurrence of fault currents only during functional testing of the first tripping circuit.

17. The method of claim 11, wherein the second break contacts are actuated by the control unit and a switching position of the second break contacts is monitored by the control unit.

18. The method of claim 11, further comprising the step of supplying electric power to the control unit from an energy storage element during functional testing of the second tripping circuit.

19. The method of claim 11, further comprising the step of reading and monitoring with the control unit a first residual-current signal which is generated by the first tripping circuit during functional testing of the first tripping circuit.
